(19) United States
(12) Patent Application Publication
(10) Pub. No.: US 2026/0140155 A1
(43) Pub. Date: May 21, 2026

(54) SIGNAL PROCESSING CIRCUIT AND SIGNAL PROCESSING DEVICE

(71) Applicant: Rohde & Schwarz GmbH & Co. KG, Muenchen (DE)

(72) Inventors: Guido Schulze, Muenchen (DE); Thomas Kuhwald, Muenchen (DE)

(21) Appl. No.: 18/948,980

(22) Filed: Nov. 15, 2024

(51) Int. Cl. G01R 29/08

(52) U.S. Cl. CPC G01R 29/0871; G01R 29/0814; G01R 29/0878

(57) ABSTRACT

A signal processing circuit includes a first signal processing channel and a second signal processing channel. The first signal processing channel includes an ADC. The first ADC is configured to digitize an RF signal, thereby obtaining a first digitized RF signal. The second signal processing channel includes a second ADC. The second ADC is configured to digitize the RF signal, thereby obtaining a second digitized RF signal. A clock distribution circuit is configured to forward a first clock signal to the first ADC and to forward a second clock signal to the second ADC. An averaging circuit is connected to both the first signal processing channel and the second signal processing channel. The averaging circuit is configured to determine a combined average of the first digitized RF signal and of a complex conjugate of the second digitized RF signal, thereby obtaining a complex-valued average signal.

### FIELD OF THE DISCLOSURE

Embodiments of the present disclosure generally relate to a signal processing circuit for processing a radio frequency signal. Embodiments of the present disclosure further relate to a signal processing device.

### BACKGROUND

With data rates becoming higher and higher, the requirements on electronic circuits regarding clock accuracy and noise generated are ever increasing. This likewise increases the measurement precision requirements when performing for example phase noise or amplitude noise measurements on the electronic circuits.

In an embodiment, when performing high-precision measurements on electronic circuits, the amplitude noise and phase noise generated by the measurement instrument itself may become a non-negligible factor that needs to be taken into account in order to ensure correct measurement results.

Thus, there is a need for a signal processing circuit and a signal processing device that minimize the influence of the signal processing circuit or of the signal processing device on measurements conducted, respectively

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a signal processing circuit for processing a radio frequency (RF) signal received from a device under test. In an embodiment, the signal processing circuit comprises at least two signal processing channels. The at least two signal processing channels comprise a first signal processing channel and a second signal processing channel, wherein the first signal processing channel and the second signal processing channel are each configured to process the same RF signal. The first signal processing channel comprises a first analog-to-digital converter (ADC) configured to digitize the RF signal, thereby obtaining a first digitized RF signal. The second signal processing channel comprises a second ADC configured to digitize the RF signal, thereby obtaining a second digitized RF signal.

In this embodiment or other embodiments, the signal processing circuit also comprises a first clock input being configured to receive a first clock signal. The signal processing circuit also comprises a second clock input being configured to receive a second clock signal. The signal processing circuit further comprises a clock distribution circuit. The clock distribution circuit is configured to forward the first clock signal to the first ADC. The clock distribution circuit further is configured to forward the second clock signal to the second ADC.

In this embodiment or other embodiments, the signal processing circuit further comprises an averaging circuit. The averaging circuit is connected to both the first signal processing channel and the second signal processing channel, wherein the averaging circuit is configured to determine a combined average of the first digitized RF signal and of a complex conjugate of the second digitized RF signal, thereby obtaining a complex-valued average signal.

It is to be understood that the first digitized RF signal and the second digitized RF signal are complex-valued signals that each correspond to the same RF signal received from the device under test.

Examples of the signal processing circuit disclosed herein are based on the idea to selectively remove noise originating from sources other than the device under test from the RF signal by averaging the cross-correlation between the first digitized RF signal and the second digitized RF signal, i.e. by averaging over a product of the first digitized RF signal and of a complex conjugate of the second digitized RF signal.

In an embodiment, the product of the first digitized RF signal and of the second digitized RF signal may be averaged over a predetermined number of samples.

For example, both the amplitudes and the phases of the digitized RF signals are taken into account for determining the combined average. In other words, the complex-valued digitized RF signals each comprise amplitude information and phase information that is considered for determining the combined average. Accordingly, the combined average may also be called a “vector average”.

By performing the combined averaging described above, the resulting complex-valued average signal comprises significantly reduced noise from sources other than the device under test. This is due to the fact that both the first digitized RF signal and the second digitized RF signal comprise noise originating from the device under test, such that these portions of the digitized RF signals are correlated with each other and do not cancel out when performing the combined average.

On the other hand, noise originating from other sources, e.g. from the signal processing channels processing the RF signal in parallel, is not correlated with each other and at least partially cancels out when performing the combined average.

Generally, as the first ADC and the second ADCs digitize the same RF signal based on different clock signals, both amplitude noise and phase noise generated by the signal processing circuit is uncorrelated with each other and at least partially cancels out when performing the combined average. On the other hand, if the same clock signal was used by both ADCs, only the amplitude noise would cancel.

Thus, embodiments of the signal processing circuit do not only allow for high-precision measurements of amplitude noise generated by the device under test, but also for high-precision measurements of phase noise generated by the device under test.

In an embodiment, the signal processing circuit allows for a fast suppression of the intrinsic noise of the signal processing circuit such that e.g. the noise level of the device under test and/or small-amplitude signals of the device under test can reliably be measured.

In an embodiment, the signal processing circuit allows to increase the signal-to-noise ratio for measurements of signals of the device under test, for example for measurements of small-amplitude signals of the device under test.

Generally, an additional reference measurement for determining the noise contribution of components in the signal chain other than the device under test is not necessary. Thus, the amplitude noise contribution and/or the phase noise contribution of the device under test can reliably be analyzed based on a single measurement.

For example, the signal processing circuit may be integrated into an oscilloscope, a digital oscilloscope, a digitizer, or any other suitable type of test and/or measurement instrument.

According to an aspect of the present disclosure, the first ADC, for example, is configured to digitize the RF signal based on the first clock signal being a sampling clock of the first ADC, wherein the second ADC, for example, is configured to digitize the RF signal based on the second clock signal being a sampling clock of the second ADC. As different sampling clocks are used by the first ADC and the second ADC, phase noise generated by the first ADC and the second ADC is not correlated and thus cancels at least partially when performing the combined average.

In an embodiment, the clock distribution circuit comprises a first switching circuit, wherein the first switching circuit is configured to selectively forward the first clock signal or the second clock signal to the first ADC. Accordingly, the first switching circuit allows to select the clock signal provided to the first ADC.

According to another aspect of the present disclosure, the clock distribution circuit, for example, comprises a second switching circuit, wherein the second switching circuit is configured to selectively forward the second clock signal or the first clock signal to the second ADC. Accordingly, the second switching circuit allows to select the clock signal provided to the second ADC.

By the first switching circuit and/or the second switching circuit, the signal processing circuit may be switchable between a first mode and a second mode. In the first mode, different clock signals may be provided to the ADCs. In a second mode, the same clock signal may be provided to the ADCs.

In an embodiment, the signal processing circuit may further comprise a first clock generator circuit and a second clock generator circuit, wherein the first clock generator circuit is configured to generate the first clock signal, and wherein the second clock generator circuit is configured to generate the second clock signal. Accordingly, the first clock signal and the second clock signal may be generated by physically different clock generator circuits, namely the first clock generator circuit and the second clock generator circuit, such that the clock signals are not correlated with each other. In particular, phase noise comprised in the first clock signal is not correlated with phase noise comprised in the second clock signal. This effects that phase noise generated by the first ADC is not correlated with phase noise generated by the second ADC, such that the phase noise cancels at least partially when performing the combined average.

According to an aspect of the present disclosure, the first clock generator circuit, for example, comprises an oven-controlled crystal oscillator. Alternatively or additionally, the second clock generator circuit comprises an oven-controlled crystal oscillator. This type of oscillator provides a particularly high frequency stability, such that it is ensured that the frequencies of the clock signals generated have exactly the desired value. Further, this type of oscillator allows to precisely control the frequencies of the clock signals provided to the first ADC and the second ADC.

However, it is to be understood that the first clock generator circuit and the second clock generator circuit may be established as any other suitable type of clock generator circuit.

In an embodiment, the first clock generator circuit is frequency-locked. Alternatively or additionally, the second clock generator circuit is frequency-locked. Thus, it is ensured that a clock signal having a particularly stable frequency is provided to the first ADC and/or to the second ADC.

In an embodiment, the first clock generator circuit may comprise a frequency-locked loop being configured to stabilize a frequency of the first clock signal. Alternatively or additionally, the second clock generator circuit may comprise a frequency-locked loop being configured to stabilize a frequency of the second clock signal.

In an embodiment, the first clock signal and the second clock signal are uncorrelated. In other words, the first clock signal and the second clock signal are statistically independent from each other. Accordingly, phase noise generated by the first ADC is not correlated with phase noise generated by the second ADC and at least partially cancels when performing the combined average over the first digitized RF signal and the second digitized RFR signal.

An aspect of the present disclosure provides that, for example, the first clock signal and the second clock signal have the same frequency. Thus, the sampling clocks of the first ADC and the second ADC have the same frequency. This ensures that the RF signal is digitized with the same sample rate by the first ADC and the second ADC, which is advantageous for performing the combined average.

In an embodiment, the averaging circuit may be configured to determine an absolute value of the complex-valued average signal, thereby obtaining an output signal. The absolute value of the complex-valued average signal is a measure for the power of the wanted signal (also called “useful signal”) of the device under test (including the noise contribution of the device under test), as other noise contributions cancel partially or completely due to the combined average performed.

According to another aspect of the present disclosure, the averaging circuit, for example, is configured to determine a real part of the complex-valued average signal, thereby obtaining an output signal. The real part of the complex-valued average signal is also an appropriate measure for the power of the wanted signal of the device under test (including the noise contribution of the device under test), for example if the predetermined number of samples over which the combined average is performed is large. However, using the real part may not be appropriate in some circumstances, e.g. if the real part is negative.

In an embodiment, the signal processing circuit further comprises an acquisition circuit, wherein the acquisition circuit comprises a first acquisition sub-circuit that is arranged downstream of the first ADC, and wherein the acquisition circuit comprises a second acquisition sub-circuit that is arranged downstream of the second ADC.

In general, the first acquisition sub-circuit is configured to further process the first digitized RF signal and/or save the first digitized RF signal in an acquisition memory. For example, further processing the first digitized RF signal may comprise up-sampling the first digitized RF signal or down-sampling the first digitized RF signal, i.e. increasing or decreasing the sample rate. As another example, further processing the first digitized RF signal may comprise up-converting or down-converting a frequency of the first digitized RF signal.

Likewise, the second acquisition sub-circuit may be configured to further process the second digitized RF signal and/or save the second digitized RF signal in an acquisition memory. For example, further processing the second digitized RF signal may comprise up-sampling the second digitized RF signal or down-sampling the second digitized RF signal, i.e. increasing or decreasing the sample rate. As another example, further processing the second digitized RF signal may comprise up-converting or down-converting a frequency of the second digitized RF signal.

In an embodiment, the acquisition circuit comprises a trigger circuit. The trigger circuit may be configured to trigger acquisition of the RF signal based on predetermined events in the RF signal. In an embodiment, the trigger circuit may be configured to control the first acquisition sub-circuit to start acquisition of the first digitized RF signal. Likewise, the trigger circuit may be configured to control the second acquisition sub-circuit to start acquisition of the second digitized RF signal.

According to an aspect of the present disclosure, the first signal processing channel, for example, may comprise a first input amplifier, and the second signal processing channel may comprise a second input amplifier. In general, the first input amplifier and the second input amplifier are each configured to amplify the RF signal.

In an embodiment, the first input amplifier may be arranged upstream of the first ADC. In an embodiment, the second input amplifier may be arranged upstream of the second ADC.

A further aspect of the present disclosure provides that the at least two signal processing channels, for example, comprise a third signal processing channel and a fourth signal processing channel. In an embodiment, the third signal processing channel and the fourth signal processing channel are each configured to process the same further RF signal. The third signal processing channel comprises a third ADC, the third ADC being configured to digitize the further RF signal, thereby obtaining a third digitized RF signal. The fourth signal processing channel comprises a fourth ADC, the fourth ADC being configured to digitize the further RF signal, thereby obtaining a fourth digitized RF signal. The clock distribution circuit is configured to forward the first clock signal to the third ADC, wherein the clock distribution circuit further is configured to forward the second clock signal to the fourth ADC, wherein the averaging circuit is connected to both the third signal processing channel and the fourth signal processing channel. The averaging circuit is configured to determine a combined average of the third digitized RF signal and of a complex conjugate of the fourth digitized RF signal, thereby obtaining a further complex-valued average signal.

In an embodiment, the RF signal and the further RF signal may correspond to two distinct RF signals. Accordingly, two different RF signals, namely the RF signal and the further RF signal, can be received and processed by the signal processing circuit simultaneously. This allows for performing measurements on multiple RF signals at the same time, for example multiple input multiple output (MIMO) measurements.

Alternatively, the RF signal and the further RF signal may correspond to different portions of the same signal to be analyzed, for example to different clock cycles of the same signal to be analyzed. Accordingly, different portions of the signal to be analyzed can be processed and analyzed by the signal processing circuit simultaneously, thereby enhancing the data rate of the signal processing circuit.

In an embodiment, the third ADC may receive the same clock signal as the first ADC, namely the first clock signal. Likewise, the fourth ADC may receive the same clock signal as the second ADC, namely the second clock signal.

The further advantages and properties described above regarding the processing of the RF signal by the first signal processing channel, the second signal processing channel, and the averaging circuit analogously apply to processing the further RF signal by the third signal processing channel, the fourth signal processing channel, and the averaging circuit.

In an embodiment, the averaging circuit may comprise a first averaging sub-circuit that is connected to the first signal processing channel and the second signal processing channel. The averaging circuit may comprise a second averaging sub-circuit that is connected to the third signal processing channel and the fourth signal processing channel.

Of course, the signal processing circuit may be configured to receive and process more than two RF signals simultaneously.

In an embodiment, the signal processing circuit may further comprise an analysis circuit. The analysis circuit is configured to perform a joint analysis based on the complex-valued average signal and the further complex-valued average signal. Accordingly, the RF signal and the further RF signal are analyzed jointly rather than individually, such that a multi-channel measurement is performed. For example, such a multi-channel analysis may be performed during MIMO measurements on the device under test.

In an embodiment, the RF signal and the further RF signal may be both received from the same device under test.

According to an aspect of the present disclosure, the signal processing circuit, for example, comprises a plurality of signal processing channels being configured to process the RF signal. In an embodiment, the signal processing channel comprises a plurality of clock inputs being configured to receive different clock signals, wherein the number of signal processing channels being configured to process the RF signal is equal to the number of clock signal inputs. Accordingly, different clock signals may be provided to each of the ADCs arranged in the different signal processing channels, thereby ensuring that the phase noise generated by the different ADCs is not correlated with each other.

Embodiments of the present disclosure further provide a signal processing device. The signal processing device comprises a signal processing circuit, include one of the signal processing circuits described above. In an embodiment, the signal processing device may comprise a signal processing circuit according to any one of the embodiments described above.

Regarding the further advantages and properties of the signal processing device, reference is made to the explanations given above with respect to the signal processing circuit, which also hold for the signal processing device and vice versa.

According to an aspect of the present disclosure, the signal processing device, for example, is a test and/or measurement instrument. For example, the signal processing device may be an oscilloscope or a digitizer. However, it is to be understood that the signal processing device may be established as any other suitable type of test and/or measurement instrument, such as a spectrum analyzer, a signal analyzer, or a vector network analyzer.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawing, wherein the only FIGURE schematically shows a test and/or measurement system with a signal processing device according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

The FIGURE schematically shows an example of a test and/or measurement system 10 comprising a test and/or measurement instrument 12 and a device under test 14. In general, the test and/or measurement instrument 12 is configured to receive and analyze RF signals received from the device under test 14 in order to assess a performance of the device under test 14.

For example, the test and/or measurement instrument 12 may be an oscilloscope, a digital oscilloscope, or a digitizer. However, it is to be understood that the test and/or measurement instrument 12 may be established as any other suitable type of measurement instrument, for example as a spectrum analyzer, a signal analyzer, or a vector network analyzer.

In an embodiment, the device under test 14 may be any type of device or electronic circuit that is configured to process and/or generate RF signals. For example, the device under test 14 may be an electronic circuit that is configured to communicate with other electronic circuits via a wired or wireless connection, for example based on PCIe Gen 6, PCIe Gen 7, WLAN or 5G.

In an embodiment, the test and/or measurement instrument 12 comprises a signal processing circuit 16 having a plurality of signal inputs 18 and a plurality of signal processing channels 20. Therein, each of the signal processing channels 20 is associated with or connected to one of the signal inputs 18.

In an embodiment, as shown in the FIGURE, the test and/or measurement instrument 12 or the signal processing circuit 16 comprises a first group 22 of signal inputs 18 and associated signal processing channels 20 that are connected to the device under test 14 via a first coupling circuit 24. In an embodiment, the first group 22 comprises m+1 signal inputs 18 and m+1 signal processing channels 20. In general, m is an integer that is greater than or equal to one, i.e. the first group 22 comprises at least two signal processing channels 20.

In an embodiment, the first coupling circuit 24 is configured to forward an RF signal received from the device under test 14 to each of the signal inputs 18 of the first group 22, such that the RF signal is forwarded to each signal processing channel 20 of the first group 22. This RF signal is labelled as “Signal A” in the FIGURE. For example, the first coupling circuit 24 may be established as a power splitter, as a directional coupler, or as any other suitable type of electronic circuit having the described functionality.

Optionally, the test and/or measurement instrument 12 or the signal processing circuit 16 further comprises a second group 26 of signal inputs 18 and associated signal processing channels 20 that are connected to the device under test 14 via a second coupling circuit 28. For example, the second group 26 comprises m+1 signal inputs 18 and m+1 signal processing channels 20. Accordingly, the number of signal processing channels 20 in the second group 26 may be equal to the number of signal processing channels 20 in the first group 22.

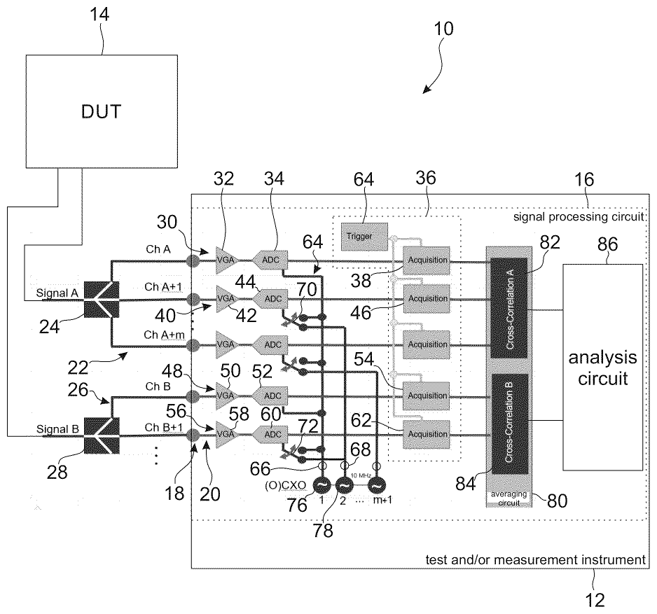

In an embodiment, the second coupling circuit 28 is configured to forward an RF signal received from the device under test 14 to each of the signal inputs 18 of the second group 26, such that the further RF signal is forwarded to each signal processing channel 20 of the second group 26. This further RF signal is labelled as “Signal B” in FIG. 1.

In an embodiment, the first group 22 of signal processing channels 20 comprises a first signal processing channel 30. The first signal processing channel 30 comprises a first input amplifier 32 that is arranged downstream of the signal input 18 associated with the first signal processing channel 30. The first input amplifier 32 is configured to amplify the RF signal received from the device under test 14 via the first coupling circuit 24.

In an embodiment, the first signal processing channel 30 further comprises a first ADC 34 that is arranged downstream of the first input amplifier 32. The first ADC 34 is configured to digitize the RF signal, thereby obtaining a first digitized RF signal. The first ADC 34 is configured to digitize the RF signal based on a first clock signal being a sampling clock of the first ADC 34, as will be described in more detail below.

In an embodiment, the signal processing circuit 16 further comprises an acquisition circuit 36 having a first acquisition sub-circuit 38, wherein the first acquisition sub-circuit 38 is provided in the first signal processing channel 30 downstream of the first ADC 34. The first acquisition sub-circuit 38 may be configured to further process the first digitized RF signal.

For example, further processing the first digitized RF signal may comprise up-sampling the first digitized RF signal or down-sampling the first digitized RF signal, up-converting a frequency of the first digitized RF signal, or down-converting a frequency of the first digitized RF signal.

Alternatively or additionally, the first acquisition sub-circuit 38 may be configured to save the first digitized RF signal in an acquisition memory, for example in a buffer memory, for example in a ring memory.

In an embodiment, the first group 22 of signal processing channels 20 further comprises a second signal processing channel 40 that is arranged in parallel to the first signal processing channel 30 and that processes the same RF signal as the first signal processing channel 30. The second signal processing channel 40 comprises a second input amplifier 42 that is arranged downstream of the signal input 18 associated with the second signal processing channel 40. The second input amplifier 42 is configured to amplify the RF signal received from the device under test 14 via the first coupling circuit 24. In an embodiment, a gain applied by the second input amplifier 42 may be equal to a gain applied by the first input amplifier 32.

In an embodiment, the second signal processing channel 40 further comprises a second ADC 44 that is arranged downstream of the second input amplifier 42. The second ADC 44 is configured to digitize the RF signal, thereby obtaining a second digitized RF signal. The second ADC 44 is configured to digitize the RF signal based on a second clock signal that may be different from the first clock signal, as will be described in more detail below. Therein, the second clock signal may be a sampling clock of the second ADC 44.

In an embodiment, the first digitized RF signal and the second digitized RF signal both correspond to the same RF signal.

In an embodiment, the acquisition circuit 36 further comprises a second acquisition sub-circuit 46, wherein the second acquisition sub-circuit 46 is provided in the second signal processing channel 40 downstream of the second ADC 44. The second acquisition sub-circuit 46 is configured to further process and/or save the second digitized RF signal analogous to the first acquisition sub-circuit 38 described above.

In an embodiment, the further signal processing channels 20 of the first group 22 are established analogously to the first signal processing channel 30 and the second signal processing channel 40 described above, and are thus not explained in more detail hereinafter.

It is emphasized that each of the signal processing channels 20 of the first group 22 receives and processes the same RF signal. However, the different ADCs of the different signal processing channels may receive different clock signals.

In an embodiment, the signal processing channels 20 of the second group 26 are also established analogously to the first signal processing channel 30 and the second signal processing channel 40 described above. However, the signal processing channels 20 of the second group 26 receive the further RF signal from the device under test 14 via the second coupling circuit 28.

In an embodiment, the second group 26 comprises a third signal processing channel 48 having a third input amplifier 50, a third ADC 52 obtaining a third digitized RF signal, and a third acquisition sub-circuit 54. The second group 26 further comprises a fourth signal processing channel 56 having a fourth input amplifier 58, a fourth ADC 60 obtaining a fourth digitized RF signal, and a fourth acquisition sub-circuit 62.

In an embodiment, the acquisition circuit 36 may comprise a trigger circuit 64. The trigger circuit 64 may be configured to control the individual acquisition sub-circuits 38, 46, 54, 62 to start acquiring the respective digitized RF signal.

In an embodiment, the signal processing circuit 16 further comprises a clock distribution circuit 64 having at least a first clock input 66 and a second clock input 68. In an embodiment, as is indicated in the FIGURE, the number of clock inputs of the clock distribution circuit 64 may be equal to the number of signal processing channels in the first group 22, for example in each of the groups 22, 26. In an embodiment, the clock distribution circuit 64 comprises m+1 clock inputs.

In general, the clock distribution circuit 64 is configured to selectively forward the different clock signals to the different ADCs 34, 44, 52, 60.

In an embodiment, the first clock signal received via the first clock input 66 is always forwarded to the first ADC 34.

In an embodiment, the first clock signal is always forwarded to the third ADC 52.

In an embodiment, the clock distribution circuit 64 comprises a switching circuit 70 that is configured to selectively connect the second ADC 44 with the first clock input 66 or the second clock input 68, such that either the first clock signal or the second clock signal can be provided to the second ADC 44. In other words, the sampling clock of the second ADC 44 can be set to be either the first clock signal or the second clock signal.

Likewise, the clock distribution circuit 64 may comprise a further switching circuit 72 that is configured to selectively connect the fourth ADC 60 with the first clock input 66 or the second clock input 68, such that either the first clock signal or the second clock signal can be provided to the fourth ADC 60.

Likewise, the clock distribution circuit 64 may comprise further switching circuits that can selectively connect the further ADCs of the signal processing channel 20 of the first group 22 and of the second group 26 to either the first clock input 66 or to one of the further clock inputs.

Optionally, the test and/or measurement instrument 12 or the signal processing circuit 16 may further comprise at least a first clock generator circuit 76 and a second clock generator circuit 78. In an embodiment, the first clock generator circuit 76 is configured to generate the first clock signal, while the second clock generator circuit 78 is configured to generate the second clock signal.

In an embodiment, the test and/or measurement instrument 12 or the signal processing circuit 16 may comprise m+1 clock generator circuits being configured to generate m+1 different clock signals for the m+1 ADCs of the first group 22 and/or for the m+1 ADCs of the second group 26.

For example, the clock generator circuits 76, 78 may each be established as an oven-controlled crystal oscillator (OCXO). However, it is to be understood that the clock generator circuits 76, 78 may be established as any other suitable type of clock generator circuit.

In an embodiment, the clock generator circuits 76, 78 may each be frequency-locked to the same frequency. For example, the clock generator circuits 76, 78 may each comprise a frequency-locked loop.

In an embodiment shown in the FIGURE, the frequency of the clock signals is 10 MHz, respectively. However, it is to be understood that the clock signals may have any other suitable frequency that is appropriate for processing or digitizing the RF signal and the further RF signal.

In an embodiment, the signal processing circuit 16 further comprises an averaging circuit 80 that is arranged downstream of the signal processing channels 20. The averaging circuit 80 comprises a first averaging sub-circuit 82 that is connected to each of the signal processing channels 20 of the first group 22. In an embodiment, the averaging circuit 80 further comprises a second averaging sub-circuit 84 that is connected to each of the signal processing channels 20 of the second group 26.

In general, the first averaging sub-circuit 82 is configured to determine at least one combined average of at least one of the digitized RF signals obtained by one of signal processing channels 20 of the first group 22 and of a complex conjugate of another digitized RF signal obtained by another one of signal processing channels 20 of the first group 22.

Without restriction of generality, the example case of a combined average of the first digitized RF signal and of a complex conjugate of the second digitized RF signal is described hereinafter. However, it is to be understood that multiple combined averages of different pairs of signal processing channels 20 of the first group 22 may be determined.

In an embodiment, the first averaging sub-circuit 82 may comprise a multiplication unit, wherein the multiplication unit is configured to multiply the first digitized RF signal with the complex conjugate of the second digitized RF signal, thereby obtaining a complex-valued multiplication signal. The first averaging sub-circuit 82 may further be configured to average the complex-valued multiplication signal over a predetermined number of samples, thereby obtaining the complex-valued average signal.

If the first digitized RF signal and the second digitized RF signal are in the frequency domain, the complex-valued average signal corresponds to a cross-correlation between the first digitized RF signal and the second digitized RF signal averaged over the predetermined number of samples. This is due to the fact that a multiplication of the digitized RF signals in frequency domain corresponds to a convolution of the digitized RF signals in time domain.

In other words, the complex-valued average signal may correspond to the trace of the cross-correlation matrix of the first digitized RF signal and the second digitized RF signal, divided by the predetermined number of samples.

Accordingly, the combined average described above may, colloquially, also be called a “cross correlation” or an “x-corr”.

The combined average described above can be performed according to an arbitrary suitable technique known in the state of the art. For example, details regarding performing the combined average are given in patent application US 2024/019470 A1, which is hereby incorporated in its entirety by reference.

In an embodiment, the first averaging sub-circuit 82 is configured to generate a first output signal based on the complex-valued average signal. For example, the first output signal may be an absolute value of the complex-valued average signal. As another example, the first output signal may be a real part of the complex-valued average signal.

Analogously to the combined average performed by the first averaging sub-circuit 82, the second averaging sub-circuit 84 is configured to determine a combined average of, for example, the third digitized RF signal and of the fourth digitized RF signal, thereby obtaining a further complex-valued average signal.

In an embodiment, the second averaging sub-circuit 84 further is configured to generate a second output signal based on the further complex-valued average signal. For example, the second output signal may be an absolute value of the further complex-valued average signal. As another example, the second output signal may be a real part of the further complex-valued average signal.

In an embodiment, the signal processing circuit 16 further comprises an analysis circuit 86. In general, the analysis circuit 86 is configured to determine at least one performance parameter of the device under test 14 based on the first output signal of the first averaging sub-circuit 82 and/or based on the second output signal of the second averaging sub-circuit 84.

For example, the analysis circuit 86 may determine at least one of an error vector magnitude (EVM) of the RF signal, an EVM of the further RF signal, a signal-to-noise ratio (SNR) of the RF signal, an SNR of the further RF signal, an amplitude noise generated by the device under test 14, a phase noise generated by the device under test 14, jitter generated by the device under test 14, etc.

In an embodiment, the analysis circuit 86 may perform a joint analysis of the first output signal and of the second output signal in order to determine the at least one performance parameter.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components, such as the test and/or measurement instrument 12, the device under test 14, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURE are not to scale. Similar elements are generally denoted by similar references in the FIGURE. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A signal processing circuit for processing a radio frequency(RF) signal received from a device under test, the signal processing circuit comprising:
at least two signal processing channels, wherein the at least two signal processing channels comprise a first signal processing channel and a second signal processing channel, wherein the first signal processing channel and the second signal processing channel are each configured to process the same RF signal,
wherein the first signal processing channel comprises a first analog-to-digital converter, ADC, the first ADC being configured to digitize the RF signal, thereby obtaining a first digitized RF signal,
wherein the second signal processing channel comprises a second ADC, the second ADC being configured to digitize the RF signal, thereby obtaining a second digitized RF signal,
wherein the signal processing circuit comprises a first clock input being configured to receive a first clock signal,
wherein the signal processing circuit comprises a second clock input being configured to receive a second clock signal,
wherein the signal processing circuit comprises a clock distribution circuit, the clock distribution circuit being configured to forward the first clock signal to the first ADC, the clock distribution circuit further being configured to forward the second clock signal to the second ADC, and
wherein the signal processing circuit further comprises an averaging circuit, wherein the averaging circuit is connected to both the first signal processing channel and the second signal processing channel, wherein the averaging circuit is configured to determine a combined average of the first digitized RF signal and of a complex conjugate of the second digitized RF signal, thereby obtaining a complex-valued average signal.

2. The signal processing circuit of claim 1, wherein the first ADC is configured to digitize the RF signal based on the first clock signal being a sampling clock of the first ADC, and wherein the second ADC is configured to digitize the RF signal based on the second clock signal being a sampling clock of the second ADC.

3. The signal processing circuit of claim 1, wherein the clock distribution circuit comprises a first switching circuit, wherein the first switching circuit is configured to selectively forward the first clock signal or the second clock signal to the first ADC.

4. The signal processing circuit of claim 1, wherein the clock distribution circuit comprises a second switching circuit, wherein the second switching circuit is configured to selectively forward the second clock signal or the first clock signal to the second ADC.

5. The signal processing circuit of claim 1, further comprising a first clock generator circuit and a second clock generator circuit, wherein the first clock generator circuit is configured to generate the first clock signal, and wherein the second clock generator circuit is configured to generate the second clock signal.

6. The signal processing circuit of claim 5, wherein the first clock generator circuit comprises an oven-controlled crystal oscillator, and/or wherein the second clock generator circuit comprise an oven-controlled crystal oscillator.

7. The signal processing circuit of claim 5, wherein the first clock generator circuit is frequency-locked, and/or wherein the second clock generator circuit is frequency-locked.

8. The signal processing circuit of claim 1, wherein the first clock signal and the second clock signal are uncorrelated.

9. The signal processing circuit of claim 1, wherein the first clock signal and the second clock signal have the same frequency.

10. The signal processing circuit of claim 1, wherein the averaging circuit is configured to determine an absolute value of the complex-valued average signal, thereby obtaining an output signal.

11. The signal processing circuit of claim 1, wherein the averaging circuit is configured to determine a real part of the complex-valued average signal, thereby obtaining an output signal.

12. The signal processing circuit of claim 1, further comprising an acquisition circuit, wherein the acquisition circuit comprises a first acquisition sub-circuit that is arranged downstream of the first ADC, and wherein the acquisition circuit comprises a second acquisition sub-circuit that is arranged downstream of the second ADC.

13. The signal processing circuit of claim 12, wherein the acquisition circuit comprises a trigger circuit.

14. The signal processing circuit of claim 1, wherein the first signal processing channel comprises a first input amplifier, and wherein the second signal processing channel comprises a second input amplifier.

15. The signal processing circuit of claim 1, wherein the at least two signal processing channels comprise a third signal processing channel and a fourth signal processing channel, wherein the third signal processing channel and the fourth signal processing channel are each configured to process the same further RF signal,
wherein the third signal processing channel comprises a third ADC, the third ADC being configured to digitize the further RF signal, thereby obtaining a third digitized RF signal,
wherein the fourth signal processing channel comprises a fourth ADC, the fourth ADC being configured to digitize the further RF signal, thereby obtaining a fourth digitized RF signal,
wherein the clock distribution circuit is configured to forward the first clock signal to the third ADC, wherein the clock distribution circuit further is configured to forward the second clock signal to the fourth ADC,
wherein the averaging circuit is connected to both the third signal processing channel and the fourth signal processing channel, wherein the averaging circuit is configured to determine a combined average of the third digitized RF signal and of a complex conjugate of the fourth digitized RF signal, thereby obtaining a further complex-valued average signal.

16. The signal processing circuit of claim 15, further comprising an analysis circuit, wherein the analysis circuit is configured to perform a joint analysis based on the complex-valued average signal and the further complex-valued average signal.

17. The signal processing circuit of claim 1, further comprising a plurality of signal processing channels being configured to process the RF signal, wherein the signal processing channel comprises a plurality of clock inputs being configured to receive different clock signals, and wherein the number of signal processing channels being configured to process the RF signal is equal to the number of clock signal inputs.

18. A signal processing device, the signal processing device comprising a signal processing circuit according to claim 1.

19. The signal processing device of claim 18, wherein the signal processing device is a test and/or measurement instrument.

20. The signal processing device of claim 19, wherein the signal processing device is an oscilloscope or a digitizer.
